(19) United States
(12) Patent Application Publication
(10) Pub. No.: US 2009/0257605 A1
(43) Pub. Date: Oct. 15, 2009

(54) MASTER VOLUME CONTROLLING DEVICE

(76) Inventor: Motoaki Shimizu, Tokyo (JP)

Correspondence Address: The Law Office of Michael E. Kondoudis, 888 16th Street, NW, Suite 800, Washington, DC, 20006, US

(21) Appl. No.: 12/353,734

(22) Filed: Jan. 14, 2009

(30) Foreign Application Priority Data
Apr. 11, 2008 (JP) 2008-103157

(51) Int. Cl. H03G 3/00

(52) U.S. Cl. 381/109

(57) ABSTRACT

A master volume can be added to a circuit included in a vacuum tube amplifier apparatus, such as a guitar amplifier apparatus etc., without troublesome modification, such as soldering to the original circuit included in the amplifier apparatus, boring a chassis in the amplifier apparatus, or the like. Concretely, a master volume can be added to a circuit included in a vacuum tube amplifier apparatus by inserting or sandwiching adaptor 53 between socket 8 for a power amplification circuit and vacuum tube 21 for the power amplification circuit, and inserting or sandwiching adaptor 54 between socket 9 for the power amplification circuit and vacuum tube 22 for the power amplification circuit, in a power amplifier included in the vacuum tube amplifier apparatus. Alternatively, an adaptor may not be attached between the vacuum tube socket for the power amplification circuit and the vacuum tube for the power amplification circuit but may be attached between a vacuum tube socket and a vacuum tube in a phase inversion circuit portion.

### CROSS-REFERENCE TO RELATED APPLICATION

This application claims priority from Japanese Patent Application No. 2008-103157 filed on Apr. 11, 2008, which was registered on Sep. 8, 2008 as Japanese Registration No. 4165902, and which is incorporated herein by reference for all purposes.

### BACKGROUND OF THE INVENTION

1. Field of the Invention

The present invention relates to a master volume controlling device mainly used for an amplifier apparatus for a musical instrument such as an electric guitar etc.

2. Description of the Related Art

An amplifier apparatus for a musical instrument, such as an electric guitar, is different from a hi-fi amplifier apparatus for audio equipment in the point that the amplifier apparatus for a musical instrument creates sound useful as a musical instrument by distorting sound signals. In the past, the distorted sound is obtained by making an amplifier apparatus over-drive by turning up the volume of the amplifier apparatus. Afterward, an amplifier apparatus which has an additional volume controller arranged at the subsequent stage of the pre-amplifier circuit was distributed. This type of amplifier apparatus can create distorted sound by over-driving the pre-amplifier circuit and turn down the volume of the distorted sound by adjusting the additional volume controller. The additional volume controller is generally called a “master volume.”

Up to now, there were only two ways to get an amplifier apparatus with a master volume. One is to buy an amplifier apparatus originally equipped with a master volume. The other is to modify an amplifier apparatus not originally equipped with a master volume. On an amplifier apparatus not originally equipped with a master volume, a master volume has to be added to the amplifier apparatus after buying the amplifier apparatus. To add the master volume to the amplifier apparatus, the wirings in the circuit in the amplifier apparatus have to be modified by means of soldering, and holes have to be prepared on the chassis of the circuit by boring the chassis or by removing some parts originally attached on the chassis, and then, variable resistors for adjusting the volume have to be attached onto the chassis by using the holes.

A vintage amplifier apparatus, which had been produced before an amplifier apparatus with a master volume appeared on the market, is not equipped with a master volume. Even now, many products of vacuum tube amplifier apparatuses not equipped with a master volume, including reproductions of vintage amplifier apparatuses, are produced.

Unlike a hi-fi amplifier apparatus for audio equipment, an amplifier apparatus for a musical instrument, such as a guitar amplifier apparatus etc., is required to have a function of creating sound useful as a musical instrument. In an amplifier apparatus for a musical instrument, if the master volume takes charge of adjusting the volume, the original volume knob that is originally attached to the amplifier apparatus focuses on the adjustment for creating the sound.

[non-patent document] Michael Doyle, “The History Of Marshall”, pages 28 to 31, 200 and 203

To add a master volume to an amplifier apparatus not equipped with a master volume, it is needed to modify the circuit in the amplifier apparatus by soldering, or it is needed to prepare holes for attaching variable resistors for adjusting the volume in the chassis in the amplifier apparatus. A vintage amplifier apparatus that maintains the original condition thereof tends to be superior to a modified vintage amplifier apparatus in resell value. The above-mentioned modification causes a loss of the original condition of the vintage amplifier apparatus, so that the value of the vintage amplifier apparatus becomes deteriorated. The above-mentioned modification is thus undesirable.

### SUMMARY OF THE INVENTION

It is therefore an object of the present invention to make it possible to easily add a master volume to a circuit included in a vacuum tube amplifier apparatus not equipped with a master volume, without the above-mentioned modification.

To achieve the above-mentioned object of the present invention, a master volume controlling device according to the present invention has a constitution in which a master volume can be added to a circuit included in a vacuum tube amplifier apparatus by attaching an adaptor to a vacuum tube socket in a power amplification circuit in a power amplifier or a vacuum tube socket in a phase inversion circuit.

According to the present invention, a master volume can be easily added to a circuit included in a vacuum tube amplifier apparatus not originally equipped with a master volume, by only connecting an adaptor to a vacuum tube socket in a power amplifier circuit or a phase inversion circuit. To add the master volume to the amplifier, modification by soldering, modification by boring a chassis, or the like is not needed.

Since modification, such as soldering, boring a chassis, or the like, is not needed, the original condition of the amplifier apparatus can be maintained, so that it is possible to prevent the value of the amplifier apparatus form deteriorating.

### BRIEF DESCRIPTION OF THE DRAWINGS

FIG. 1 is an outline perspective view showing an embodiment of a master volume controlling device of one aspect of the present invention (embodiment 1);

FIG. 2 is a view showing a circuit of the master volume controlling device; and

FIG. 3 is an outline perspective view showing an embodiment of a master volume controlling device of another aspect of the present invention (embodiment 2).

### DETAILED DESCRIPTION OF THE PREFERRED EMBODIMENTS

Embodiments of the present invention will now be discussed, with reference to drawings.

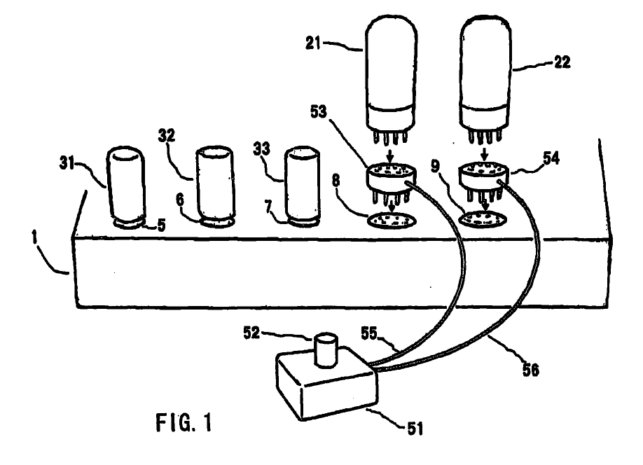

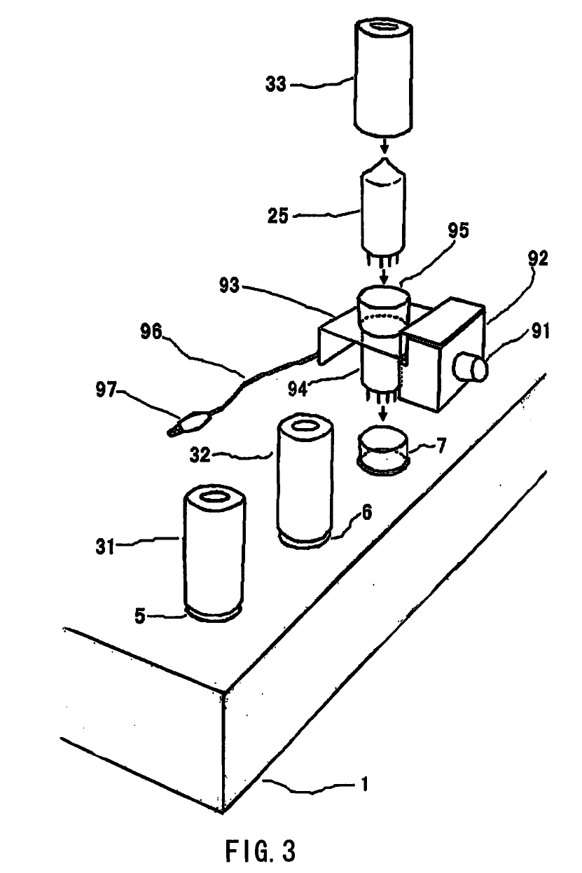

As shown in FIG. 1, in a master volume controlling device according to one aspect of the present invention, a master volume is connected to an amplifier apparatus by attaching adaptors between vacuum tube sockets and vacuum tubes in a power amplification circuit in a power amplifier included in the amplifier apparatus respectively. In a master volume controlling device according to another aspect of the present invention, a master volume is connected to an amplifier apparatus by not attaching the adaptors between the vacuum tube sockets and the vacuum tubes in the power amplifier circuit as shown in FIG. 1 but attaching an adaptor between a vacuum tube socket and a vacuum tube in a phase inversion circuit portion included in the amplifier apparatus as shown in FIG. 3.

By connecting the master volume to the amplifier apparatus as mentioned above, the volume level of a signal generated by a pre-amplifier circuit included in the amplifier apparatus can be reduced by the master volume.

### Embodiment 1

FIG. 1 is an outline perspective view showing an embodiment of the master volume controlling device according to one aspect of the present invention and a vacuum tube amplifier apparatus for a musical instrument. The master volume controlling device can be preferably used for a vacuum tube amplifier apparatus with a push-pull circuit. In FIG. 1, the master volume controlling device according to said one aspect of the present invention includes the constitutional elements indicated by reference numbers 51 to 56 (i.e., a master volume case 51, a master volume knob 52, an adaptor 53, an adaptor 54, a cable 55 and a cable 56). Concretely, the master volume controlling device includes a master volume, the adaptors 53 and 54. The master volume includes the master volume case 51, the master volume knob 52, the cables 55 and 56. Reference number 1 indicates a chassis of the vacuum tube amplifier apparatus for a musical instrument, and reference numbers 6 to 9 indicate vacuum tube sockets arranged on the chassis 1, respectively (i.e., a vacuum tube socket 6 for a pre-amplifier, a vacuum tube socket 6 for the pre-amplifier, a vacuum tube socket 7 for a phase inversion circuit, a vacuum tube socket 8 for a power amplification circuit, and a vacuum tube 9 for the power amplification circuit). In the original state, vacuum tubes 21 and 22 are directly connected to the sockets 8 and 9, respectively. When using the master volume controlling device, the adaptors 53 and 54 of the master volume controlling device are connected to the sockets 8 and 9 respectively, and the vacuum tubes 21 and 22 for the power amplification circuit are connected to the adaptors 53 and 54 of the master volume controlling device respectively. Incidentally, reference numbers 31 and 32 indicate shield covers for vacuum tubes for pre-amplifier circuit, respectively. Reference number 33 indicates a shield cover for the vacuum tube for the phase inversion circuit.

FIG. 2 is a view showing a circuit in the master volume controlling device. In the master volume controlling device, a connecting point 71 is connected to a control grid of the vacuum tube 21 for the power amplification circuit via the adaptor 53 shown in FIG. 1. A connecting point 72 is connected to a control grid of the vacuum tube 22 for the power amplification circuit via the adaptor 54 shown in FIG. 1. In the amplifier apparatus with the push-pull circuit, the phase of an alternating current signal representing sound in the control grid of the vacuum tube 21 for the power amplification circuit is opposite to the phase of an alternating current signal representing sound in the control grid of the vacuum tube 22 for the power amplification circuit. Therefore, the alternating current signals passing through the variable resistors 81 and 82 cancel each other out by connecting the variable resistors 81 and 82 to each other. Thus, the volume of the sound can be adjusted. The variable resistors 81 and 82 are the resistance elements of a dual variable resistor, respectively. Both of the resistances of the variable resistors 81 and 82 can be varied by adjusting a single control knob of the dual variable resistor. A capacitor 83 plays the role in adjusting the volume by allowing only the alternating current signals representing sound to ground. In the case that the vacuum tube amplifier apparatus has a circuit in which a cathode of each vacuum tube for the power amplification circuit is connected to a ground, a connecting point 73 can be connected to the ground by connecting the connecting point 73 to a connecting hole of the socket 8 or 9 for connecting a cathode terminal of a vacuum tube for the power amplification circuit through the adaptor 53 or 54 shown in FIG. 1.

### Embodiment 2

FIG. 3 is an outline perspective view showing an embodiment of the master volume controlling device according to another aspect of the present invention and a vacuum tube amplifier apparatus for a musical instrument. The master volume controlling device can be preferably used for a vacuum tube amplifier apparatus with a phase inversion circuit in which alternating current signals representing sound, the phases of which are opposite to each other, are respectively supplied to two plates of a vacuum tube in the phase inversion circuit. In FIG. 3, the master volume controlling device according to said another aspect of the present invention includes the constitutional elements indicated by reference numbers 91 to 97 (i.e., a master volume knob 91, a master volume case 92, a chassis 93 for adaptors, an adaptor 94 (a plug portion), an adaptor 95 (a socket portion), a ground line 96 and a clip terminal 97 for grounding). Concretely, the master volume controlling device includes a master volume, the adaptors 94 and 95. The master volume includes the master volume knob 91, the master volume case 92, the chassis 93 for adaptors, the ground line 96 and the clip terminal 97 for grounding.

The master volume controlling device has a circuit having the same constitution as that of the circuit shown in FIG. 2. Connecting points 71 and 72 in FIG. 2 are respectively connected to the two plates of a vacuum tube 25 for the phase inversion circuit in FIG. 3. Connecting point 73 is connected to the ground line 96 in FIG. 3. The ground line 96 is grounded by fastening the clip terminal 97 for grounding to a projection, such as a screw, on the chassis 1 of the vacuum tube amplifier apparatus for a musical instrument.

The invention may be embodied in other specific forms without departing from the spirit or essential characteristics thereof. The present embodiments are therefore to be considered in all respects as illustrative and not restrictive, the scope of the invention being indicated by the appended claims rather than by the foregoing description and all changes which come within the meaning and range of equivalency of the claims are therefore intended to be embraced therein.

The entire disclosure of Japanese Patent Application No. 2008-103157 filed on Apr. 11, 2008 including the specification, claims, drawings and summary is incorporated herein by reference in its entirety.

What is claimed is:

1. A master volume controlling device comprising:
a master volume for reducing a volume level of a signal generated by a pre-amplifier circuit included in a vacuum tube amplifier apparatus; and
an adaptor for connecting the master volume to a socket for a vacuum tube in a power amplification circuit in a power amplifier included in the vacuum tube amplifier apparatus.

2. A master volume controlling device comprising:
a master volume for reducing a volume level of a signal generated by a pre-amplifier circuit included in a vacuum tube amplifier apparatus; and
an adaptor for connecting the master volume to a socket for a vacuum tube in a phase inversion circuit portion included in the vacuum tube amplifier apparatus.
